(19) United States
(12) Patent Application Publication
(10) Pub. No.: US 2002/0094038 A1
(43) Pub. Date: Jul. 18, 2002

(54) Error-correcting code decoding method and error-correcting code decoding apparatus

(75) Inventor: Toshihiko Okamura, (US)

Correspondence Address: David A. Blumenthal, FOLEY& LARDNER, Washington Harbour, 3000 K Street, N.W., Suite 500, Washington, DC, 20007-5109, US

(73) Assignee: NEC CORPORATION

(21) Appl. No.: 09/942,671

(22) Filed: Aug. 31, 2001

(30) Foreign Application Priority Data
Jan. 9, 2000 (JP) 2000-265785

(51) Int. Cl. H03D 1/00; H04L 27/06

(52) U.S. Cl. 375/340

(57) ABSTRACT

In a case where a soft input and soft output decoding method is applied to a decode processing carrying out repeated decode processing, preparing a plurality of kinds of block that is a unit of decode processing, setting the size of blocks that are initially processed for every kind of the repeated decode processing at different values of size.

### BACKGROUND OF THE INVENTION

1. Field of the Invention

The present invention relates to an error-correcting code decoding apparatus for decoding data that are coded by an error-correcting code, and more particularly, it relates to an error-correcting code decoding method and apparatus suitable for use for decoding of concatenated codes, typically turbo codes.

2. Description of the Related Art

The art of coding by the error-correcting code is a technique for restoring data at a high probability by the operation of coding and decoding even if an error such as a bit inversion happens on a channel during transmission of the data. At the present time, the art of coding by the error-correcting code is widely used in the field of wireless communication and a digital recording medium. The coding is a kind of converting operation by which data (i.e., a sequence of transmitted information) are converted into code words by providing redundancy to such data. The decoding is a kind of estimating operation by which the original data are estimated from the received words containing therein an error or errors by the use of the above-mentioned redundancy.

The soft output decoding method is a decoding method of outputting conditional probability of information symbols or code word symbols under the received word, and are also referred to as a posteriori probability decoding method. In a case where the information symbols of a coding subjects are binary digits (0 and 1), L (u (k)) represented by below equation (1) may be generated in the posteriori probability decoding method.

L(u(k))=log (P(u(k)=0|Y)|P(u(k)=1|Y) (1)

Where u(k) is a kth information bit, Y is a received word, and P(u(k)=b|Y) (b=0,1) is a conditional probability to become U(K)=b under the received word Y.

In particular, as a decoding method for the code capable of being represented by the trellis diagram having a smaller state number, a posteriori probability decoding method in which an amount of calculation is comparatively small is known. An algorithm for realizing such posteriori probability decoding method is a technical skill that is constituted by complicating the Viterbi decoding known as a maximum likelihood decoding method of conventional convolutional codes, and is referred to as either the BCJR (Bahl,Cocke, Jelnek, and Raviv) algorithm or MAP (maximum a posteriori) algorithm. A detailed description of the MAP algorithm is provided in, for example, “Optimal decoding of linear codes for minimizing symbol error rate” (IEEE Transaction on Information Theory, PP.284-287, 1974).

The MAP algorithm is a decoding method outputting 5 not a result of a hard decision in which the received words are directly decided as “0 ” or “1” but a result of a soft decision, i.e., a value formed by adding a reliability to the result of decision of the respective bits, and is also referred to as a soft input and soft output decoding method. A further description will be given hereinbelow provided that the information symbols are binary digits but will be easily enlarged to the case that the information bits are multiple-values.

In the soft input and soft output decoding method, diverse methods have been investigated for reducing the amount of calculation by obtaining not the L(u(k)) of equation (1) but an approximation of the L(u(k)). The Max-Log-MAP algorithm and the SOVA (soft output Viterbi algorithm) can be typical technical skills of the soft input and soft output decoding method. The detailed description of these algorithms is provided in, for example, “A Comparison of optimal and sub-optimal MAP decoding algorithms” (ICC′ 95, pp.1009-1013, 1995).

By the way, a high performance code referred to as a turbo code has been proposed by C. Berrou et al., in 1993. The description of the turbo code is provided in “Near Shannon limit error-correcting coding and decoding: Turbo codes” (ICC′ 93, pp.1064-1070, 1993).

FIG. 1A is a block diagram illustrating a typical construction of the turbo encoder and FIG. 1B is a typical construction of the turbo decoder.

As shown in FIG. 1A, the turbo encoder has such a construction that two systematic convolutional coding devices in which a feedback loop including a non-illustrated delay element and a non-illustrated exclusive OR is formed, are juxtaposed via an interleaver.

In the convolutional coding process by first and second systematic convolutional coding devices 100 and 101 are used code normally having memories which is equal to or smaller than four. Interleaver 102 is a device for re-arranging respective bits of an information sequence that are coded subject, according to a predetermined rule, and the coding performance depends on the processing system taken by interleaver 102. At this stage, it should be noted that turbo encoder outputs the information sequence with the parity 1 and the parity 2 that are sequences of redundancy, respectively.

On the other hand, as shown in FIG. 1B, the turbo decoder has such a construction that there are provided two decoders in conformity with the arrangement of the turbo encoder shown in FIG. 1A. First decoder 103 is a decoder that is provided so as to be in conformity with first systematic convolutional coding device 100, and second decoder 105 is a decoder that is provided so as to be in conformity with the second systematic convolutional coding device 101.

The turbo decoder has the feature that first and second decoders 103 and 105 use the above-mentioned soft input and soft output decoding method. First decoder 103 carries out decoding by applying a soft output processing to respective information bit sequences generated by second decoder 105, so that a weight value is attached to the received data. The soft output generated by second decoder 105 is not the value of L (u(k)) calculated from the equation (1) but the values of Le (u(k)) calculated from the L (u(k)) and referred to as extrinsic information represented by an equation (2) below.

Le(u(k))=L(u(k))−C·y(k)−La(u(k)) (2)

Where y(k) is a received value for the information bit u(k), La(u(k)) is a value given by second decoder 105, and C is a constant determined by the SN ratio of a communication line. The practical values of the Le(u(k)) are rearranged by deinterleaver 106 so as to conform with the order of the information bit sequences in first decoder 103.

Le(u(k)) calculated by using the equation (1) in first decoder 103 are used as an a priori distribution values by second decoder 105. In this case, the practical values of the Le(u(k)) are also rearranged by interleaver 104 so as to conform with the order of the information bit sequences.

As described above, the feature of the turbo decoder resides in that the decode processing is repeatedly carried out by sequentially renewing the extrinsic information between the two decoders. Whenever the decode processing is repeated, error rate in decoding is sequentially improved, and approximately ten times of repetition is normally sufficient. The finally obtained value L (u(k)) of the soft output resulting from the repeated decode processing is subjected to a hard decision to obtain decoded data.

Next, a further detailed description of the MAP algorithm (BCJR algorithm) will be provided hereinbelow.

The MAP algorithm is an algorithm utilizing the trellis diagram of the code in a manner similar to the Viterbi algorithm which is well known as the maximum likelihood decoding. In the trellis diagram, each path corresponds to a code word. In particular, a time-unchanged convolutional code is characterized in that it has a trellis structure not depending on time. Thus, when the number of states at each time is small, it becomes easy to carry out the algorithm utilizing the trellis diagram.

The MAP algorithm can be largely classified into three kinds of processes below.

(a) Forward process:

Calculating a probability of arriving at each state at each time from the initial of the trellis diagram.

(b) Backward process:

Calculating a probability of arriving at each state at each time from the termination of the trellis diagram.

(c) Soft output generation process:

Calculating a post-probability ratio of information bits at each time by using the results of the processes (a) and (b) above.

The state set of the convolutional codes is expressed by S={0,1, . . . , |S|−1}, the time is expressed by “t”, the values calculated during the forward process and backward process at the state “s” are expressed by α (t,s), and β(t,s), respectively. Further, a probability of transition at the time “t” from the state “s” to the state “s′” is expressed by γ(t,s,s′). The γ(t,s,s′) can be calculated as a likelihood between the code word corresponding to the transition from the “s” to “s′” and the received value. The γ(t,s,s′) can be easily calculated by using the SN ratio of channel in the white Gaussian channel. At this time, the forward and backward processes are put into practice by using a value once before or later.

(a) The forward process:

α(t,s)=Σα(t−1, s′)γ(t,s′,s)

(b) The backward process:

β(t,s)=Σβ(t+1,s′)γ(t+1,s,s′)

where the sum (Σ) in the above equations means that the calculation is conducted at all of the states s′. Further, the post probability ratio at the time “t” can be calculated by using α(t-1, s), γ(t,s,s′) and β(t, S).

The Max-log-MAP algorithm calculates the logarithmic values α′, β′, γ′ of α, β, γ in the above processes (a) and (b) to thereby convert the operation processing from the product to the sum, and converts the Σ to the calculation to obtain the maximum value. In other words, in the Max-log-MAP algorithm, the above (a) and (b) are changed to (a′) and (b′) as set below.

(a′) The forward process:

α′(t,s)=max {α′(t−1,s′)+γ′(t,s′,s)}

(b′) The backward process:

β′(t,s)=max {β′(t+1,s′+γ′(t+1,s,s′)}

Where the processing max to obtain a maximum value means obtaining such values in all of the states s′. An important feature of the Max-log-MAP algorithm resides in that it does not need any operation processing for obtaining a product, which are needed by the MAP algorithm.

The process (a′) corresponds to the ACS processing (Add-Compare-Select processing) in the normal Viterbi algorithm, and the process (b′) corresponds to a reverse processing in which the ACS processing is carried out reversely from a terminate portion of the trellis diagram to the initial point.

In the MAP algorithm and the Max-log-MAP algorithm, either the values of α and β at each time in each state of the trellis code must be stored.

Also, in the turbo coding, a large code length he number of information bits is approximately equal to or larger than 500) is processed although the number of states is small, and therefore the turbo code is needed to be sequentially decoded by utilizing any one part of the trellis diagram, from the viewpoint of practical assembly. This can be carried out by a trellis truncation method used in the Viterbi algorithm.

FIG. 2 illustrates the construction of an apparatus for decoding an error-correcting code according to the prior art.

The error-correcting code decoding apparatus of FIG. 2 is provided with its construction that is used in, for example, first decoder 103 and second decoder 105 shown in FIG. 1B.

In FIG. 2, an a priori distribution value storing device 71 is a device for storing the reliability information of either bit or symbol of a code word. The reliability information in the turbo decoding corresponds to an extrinsic information Le(u(k)) of each information bit generated by the other decoder. Input controlling device 72 reads out data of necessary times from received value storing device 70 and an a priori distribution value storing device 71, and supplies the read data to soft output generating device 73. Soft output generating device 73 produces a soft output by employing the soft input and soft output decoding method such as the MAP algorithm and the Max-log-MAP algorithm. At this stage, these algorithms need the backward process, and this fact is largely different from the conventional Viterbi algorithm.

If a natural status in which decoding is carried out from the initial time is assumed, the forward process is started from the initial state of the trellis while being sequentially renewed. However, since the backward process is started from the terminate state of the trellis, there occurs problems such that the backward process should be started from what point in the midway of the trellis, and how the initial value should be set.

In order to solve the above-mentioned problems, there has been proposed a method, which is referred to as a sliding window method described in detail in, for example, “Soft-output decoding algorithms for continuous decoding of parallel concatenated convolutional codes” (ICC′ 96, pp.112-117, 1996).

The sliding window method is a method to carry out the backward process under an assumption such that respective states at t+T (T is a sufficiently large predetermined value) have an equal probability when a soft output at the time t is calculated.

Hardware architecture capable of sequentially obtaining soft outputs due to pipelining by utilizing the sliding window method has been proposed in, for example, “VLSI architectures for turbo codes” (IEEE Transactions on VLSI systems, pp.369-379, 1999).

In this architecture, the number of backward process times for one information symbol is T. Except for the sliding window method, since the backward process may be usually carried out only once from the terminate state to the initial state, it should be noted that the backward process carried out once as per a single information symbol is sufficient.

Also, a method of obtaining sequential soft outputs by allowing the backward process shifted T points in time to implement in parallel is described in “An intuitive justification and a simplified implementation of the MAP decoder for convolutional codes” (IEEE Journal on Selected Areas in Communications, pp.260-264, 1998). In this method, the number of the backward process times for one information symbol is two. Thus, when the decoding of soft outputs is carried out by employing a partial point in time of the trellis diagrams, an amount of the backward process is increased.

The above-described decoding method is a method by which an increase in the amount of backward process that occurs due to the employment of a part of the trellis diagrams is solved by employing the architecture having a high degree of parallelism.

On the other hand, when the decoding is carried out by employing a part of the trellis diagrams in the architecture having a low parallelism such as DSP (Digital Signal Processor), it is necessary to reduce an amount of calculation of the backward process for one information symbol for an improvement in the decode processing speed.

In this case, it is effective that the code words are divided into a plurality of blocks, so as to generate a soft output for each of the plurality of blocks.

Hereinbelow, a unit (=a reference value of the size of a block) of the number of points in time for producing a soft output is defined as “B”.

FIG. 3 is a chart illustrating the flow of control, and is a flow chart illustrating a sequence of processing in the error-correcting code decoding apparatus according to the prior art, which generates a soft output for every block.

As shown in FIG. 3, in the error-correcting code decoding apparatus according to the prior art, the residual number R of points in time of the received data (residual data time number R) except for the terminate portion of the trellis is firstly checked (Step D1). If the residual data time number R is equal to or larger than B, the size of block is set at B (Step D2). If the residual data time number R is smaller than B, the size of block is set at R (Step D3). Accordingly, in Step D3, the normal backward process is carried out from the terminate portion of the trellis.

FIG. 4 illustrates how the received data is decoded according to the flow chart of FIG. 3. At this stage, it should be understood that block numbers 1, 2, . . . are given to the respective blocks from the initial point in time toward the terminate point in time.

As shown in FIG. 4, in the error-correcting code decoding apparatus, first of all, the forward process F(1) and the backward process BW(1) are carried out respectively, for the block 1 having the size B. Since the initial value of the forward process corresponds to the initial point of the trellis diagram, there is no problem. Nevertheless, as described before, the initial value of the backward process makes the respective states to be in equal probability. At this time, the backward process is commenced from the point (B+T) in time by a margin of the number T of time point in order that the β at the boundary of blocks takes a significant value. Namely, in order to decode the received data at the time point B, it is necessary that input controlling device 72 must supply soft output generating device 73 with the received data for the block boundary (B+T) time points from received value storing device 70 and a priori distribution value storing device 71. When the forward process F(1) and the backward process BW(1) for the block 1 are terminated, a soft output generating processing G(1) is implemented.

When all processes for the block 1 are terminated, the decoding operation is moved to the process for the block 2 (F(2), BW(2), and G(2)). At this instance, the value of α at the terminate point B in time of the block (1) is again used as the initial value of the forward processing F(2). The backward process BW(2) is started with the initial value thereof based on the fact that respective states from the time point (2B+T) have an equal probability. In this method, the backward process for one information symbol becomes those for the points (1+T/B) in time. Further, with regard to the forward process and the soft output generating process, those for one information symbol corresponds to those for one point in time.

As described above, in the decoding method of the prior art, shown in FIGS. 3 and 4, since the backward process for one information symbol corresponds to that for the time points (1+T/B), the amount of calculation in the backward process can be reduced by setting the margin time points T of the backward process at a small value for the block size B.

In order to prevent the size of the apparatus from being increased, it is desirable that the block size B and the value of the margin time points T are reduced. However, a reduction in the value of the margin time points T of the backward process will brings about a deterioration in the decoding performance. For example, in the case where a soft input and soft output decoding is applied to a decoder for turbo codes constituted by concatenating convolutional coders having three memories, respectively, a deterioration in the decoding performance cannot be recognized when T=24 through 30. However, it was confirmed from the experiments that when T=15, a deterioration in the coding gain equal to or more than 0.4 dB occurs at the decoding frame error ratio 0.0001.

On the other hand, if it is assumed that each of the forward process, the backward process and the soft output generating process requires an equal amount of calculation, the forward process and the soft output generating process are a processing of one point in time as per one information symbol, respectively, and the backward process is a processing of (1+T/B) point in time as per one information symbol. Therefore, the values of T and B have an influence on the total amount of calculation at the ratio of 1+1+(1+T/B)=3 +T/B. For example, when it is assumed that B=32, it is possible to reduce the amount of calculation by changing T=24 to T=15. Accordingly, it is very important to reduce the margin time point T of the backward process at the block boundary for the purpose of reducing the amount of calculation in the decoding.

### SUMMARY OF THE INVENTION

Therefore, an object of the present invention is to provide a method of and apparatus for error-correcting code decoding in which a soft input and soft output method is applied to a decoding that implements a repeated decode processing, even if the margin time points T of the backward process at the block boundary is set small, any deterioration in the decoding performance occurs.

In order to achieve the above object, in the error-correcting code decoding method and apparatus according to the present invention, a plurality of kinds of blocks is set, and the size of blocks which are initially decoded for every kind are set at different values in the repeated decode processing. Further, the residual blocks except for the finally processed block are set at a predetermined reference size, respectively.

In the error-correcting code decoding method and apparatus according to the prior art, when the margin time point T is set small, a deterioration in the decoding performance occurs, and in some error pattern, there are a case where decoding can be implemented and a case where decoding cannot be implemented, depending on a manner of setting of the block boundary.

In accordance with the present invention, the sizes of the initial blocks for every kind are set at different values in the repeated process, and therefore setting values of the block boundaries are increased to thereby enhance the probability that the decoding can be implemented. That is to say, when the margin time point T is set small, if decoding can be implemented at any block boundary, the data with no error can be decoded at a high probability without increasing the number of repetition of the decoding processing. Thus, it is possible to reduce the amount of calculation in the backward process without occurrence of any deterioration in the decoding performance.

The above and other objects, features, and advantages of the present invention will become apparent from the following description based on the accompanying drawings which illustrate examples of preferred embodiments of the present invention.

### BRIEF DESCRIPTION OF THE DRAWINGS

FIG. 1A is a block diagram illustrating a typical construction of the turbo encoder;

FIG. 1B is a block diagram illustrating a typical construction of the turbo decoder;

FIG. 2 is a block diagram illustrating the construction and arrangement of the error-correcting code decoding apparatus according to the prior art;

FIG. 3 is a flow chart illustrating the processing steps of the error-correcting code decoding apparatus of the prior art, which generates a soft output for every block;

FIG. 4 is a diagrammatic view illustrating how the received data are decoded according to the flow chart of FIG. 3;

FIG. 5 is a block diagram illustrating an example of construction of the error-correcting code decoder according to the present invention;

FIG. 6 is a flow chart illustrating an example of the processing steps of the controlling information generating apparatus of FIG. 5;

FIG. 7 is a diagrammatic view illustrating how the received data are decoded according to the flow chart of FIG. 6;

FIG. 8 is a flow chart illustrating another example of the processing steps of the control command generating device of FIG. 5;

FIG. 9 is a diagrammatic view illustrating the result of processing conducted by the control command generating device of FIG. 5; and, FIG. 10 is a flow chart illustrating the processing steps in the case where the processing of FIG. 6 is applied to the turbo decoder.

### DETAILED DESCRIPTION OF THE PREFERRED EMBODIMENTS

As shown in FIG. 5, the error-correcting decoding apparatus according to the present embodiment is constructed so as to include received value storing device 10 for storing the received data, an a priori distribution value storing device 11 for holding an a priori distribution value corresponding to the reliability of information symbols, soft output generating device 13 for generating soft outputs of each information symbol by the unit of block, based on the received data and the an a priori distribution values, input controlling device 12 for reading data from received value storing device 10 and an a priori distribution value storing device 11 and for supplying the read data to soft output generating device 13, and control command generating device 14 for forcing input controlling device 12 to alter the boundary of block depending on the number of times of repeated decode processing.

Control command generating device 14 prepares a plurality of kinds of blocks, and sets the respective sizes of the initial blocks for every kinds in the repeated decode processing at different values, depending on the number of times of repetition. For example, when the two kinds of blocks are prepared, control command generating device 14 sets the size of the initial block at a given size (e.g., B/2) different from the reference size B at either an odd number of time or an even number of time of the repeating times of the repeated decode processing.

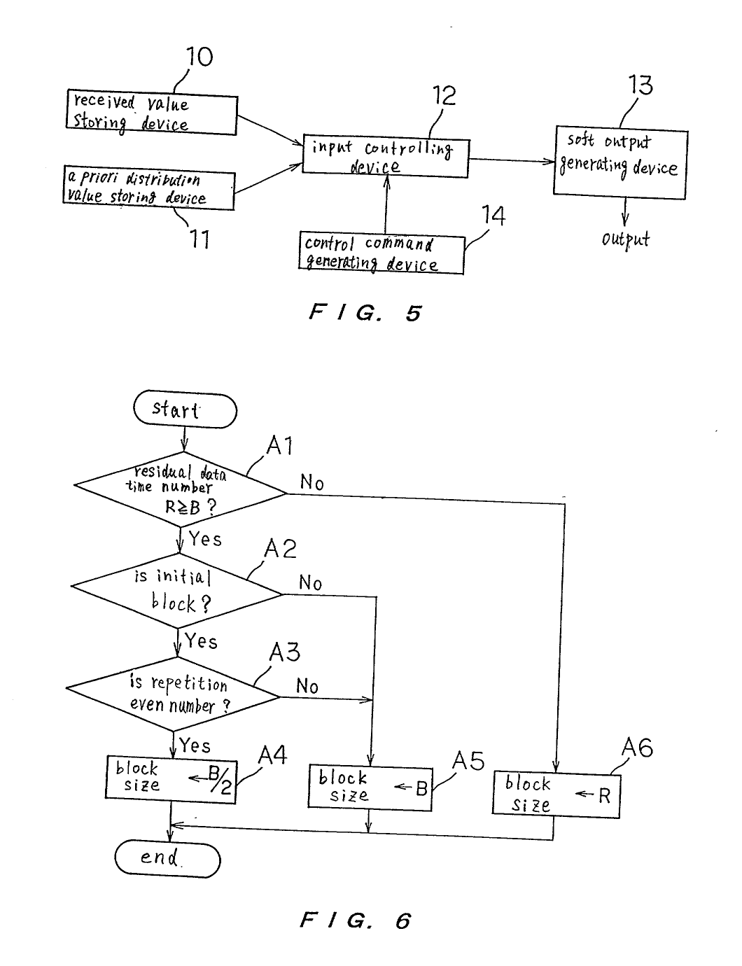

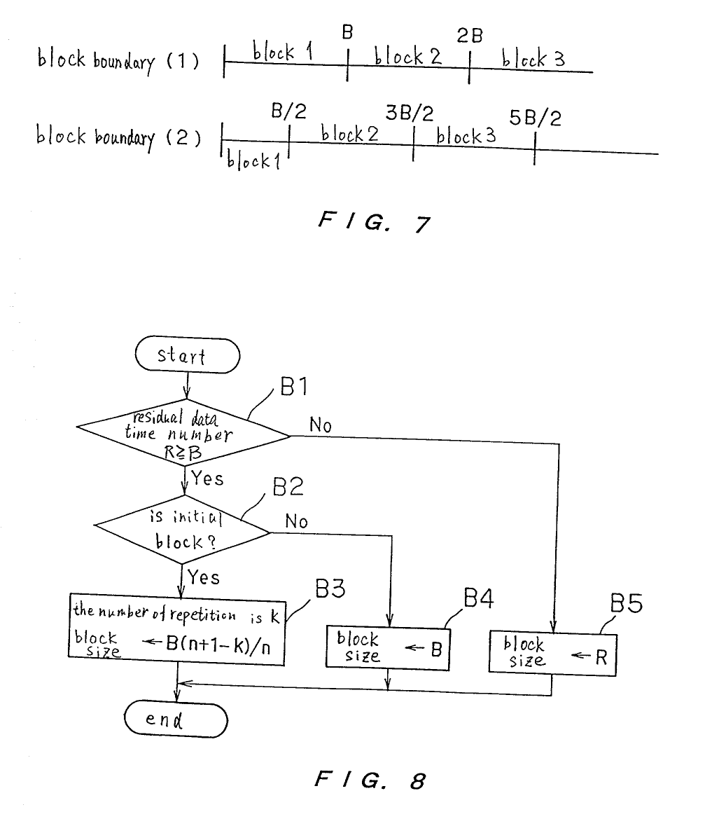

In this construction, the operation of the error-correcting code decoding apparatus of the present embodiment will be described more in detail with reference to FIGS. 6 and 7. At this stage, it should be noted that the description below is provided with an example in which two kinds of blocks are prepared.

As shown in FIG. 6, first of all, control command generating device 14 checks the number R of points in time of residual data (residual data time number R) that do not complete the soft output generation (Step A1). When the residual data time number R is smaller than B, the size of block is set at R (Step A6). Further, when the residual data time number R is equal to or larger than B, control command generating device 14 decides as to whether or not the data for the subject of soft output generation is the initial block (Step A2). As a result of the process of the step A2, when the data for the subject of the soft output generation is not an initial block, the size of block is set “B” (Step A5). When the data for the subject of the soft output generation is an initial block, control command generating device 14 checks the number of repetition of the repeated decode processing at this instant is an even number of repetition or an odd number of repetition (Step A3). When the number of repetition is an even number, the size of the initial block is set “B/2” (Step A4). Also, when the number of repetition is an odd number, the size of the initial block is set “B” (Step A5).

According to the operation of control command generating device 14, when the number of repetition of the repeated decode processing is an odd number, the boundaries of the blocks are set as shown in (1) of FIG. 7, and when the number of repetition of the repeated decode processing is an even number, the boundaries of the blocks are set as shown in (2) of FIG. 7. Thus, the soft output generating process is carried out for every unit of block. Namely, between the odd number and the even number of repetition of the repeated decode processing, the boundaries of blocks are shifted from one another by an amount of B/2 points in time. It should be noted that setting of boundaries of blocks at “B” and “B/2” might be reversed between the odd and even numbers.

In the error-correcting code decoding method of the prior art, when the margin points in time T is set small, a deterioration in the decoding performance occurs, and therefore in some error pattern or patterns, there occurs either a case where decoding can be done or a case where decoding cannot be done, depending on a manner of setting of the block boundaries. At this stage, there might be a decoding method in which decoding is carried out by using two block boundaries, and when it is confirmed that correct decoding could be done with one of the two block boundaries, such correct decoding is directly used as a decoding result. However, this method will bring about an increase in the amount of calculation.

In the present embodiment, since the sizes of the initial blocks are changed with every kind of block in the repeated decode processing so as to increase the number of the setting value of the block boundaries, an increase in a probability that the decoding can be correctly done will be achieved. Namely, even when the margin points of time T is set small, if the decoding can be correctly done with any block boundary, the data having no error can be decoded at a high probability without an increase in the number of repetition of the repeated decode processing.

In the foregoing, although there is provided a description of an example of alternately using two kinds of blocks in decoding process for carrying out the repeated decode processing, it should be understood that this method will, of course, be applicable to not only the described case of using two kinds of blocks but a case where three or more kinds of blocks are used.

Next, the description of the operation of the error-correcting code decoding apparatus when using n (n=integer) kinds of block boundaries will be provided hereinbelow with reference to FIG. 8.

As shown in FIG. 8, control command generating device 14 first confirms the number R of points in time of the residual data (residual data time number R) that have not yet completed generation of any soft output (Step B1). When the residual data time number R is smaller than B, the size of the block is set R (Step B5). Also, when the residual data time number R is equal to or larger than B, control command generating device 14 decides as to whether or not the data for the subject of soft output generation is the initial block (Step B2). When the data for the subject of soft output generation is not the initial block, the size of block is set B (Step B4). Further, when the data for the subject of soft output generation is the initial block, the number of repetition of the present instant is confirmed, and when the number of repetition is k, the size of block is set the following equation (3) (Step B3).

B(n+1−k)|n (3)

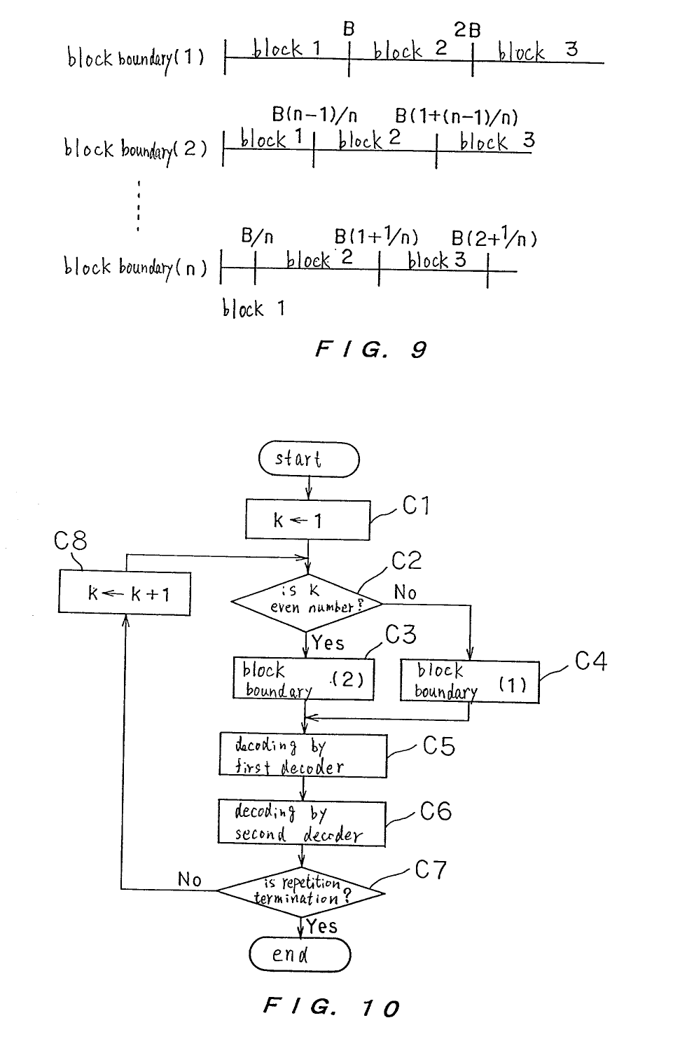

FIG. 9 illustrates the result of processing by control command generating device 14 shown in FIG. 5, and illustrates how the boundaries of the n blocks are set when the reference size of the block is B.

It should be noted that the setting of the block boundary in a case where the number of repetition of the repeated processing is k in the steps shown in FIG. 8, corresponds to the block boundary (k mod n) of FIG. 9. At this stage, the k mod n above indicates the value of k under the modulo n, and the value k can be 1 through n.

In this manner, when the kind of block is increased, the setting value of the block boundary is in turn increased, and accordingly the data having no error can be decoded at a high probability.

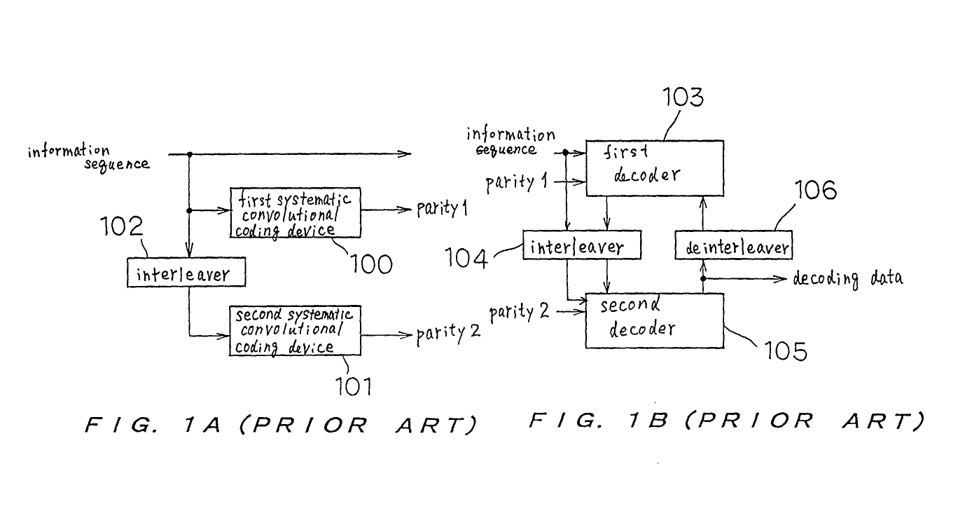

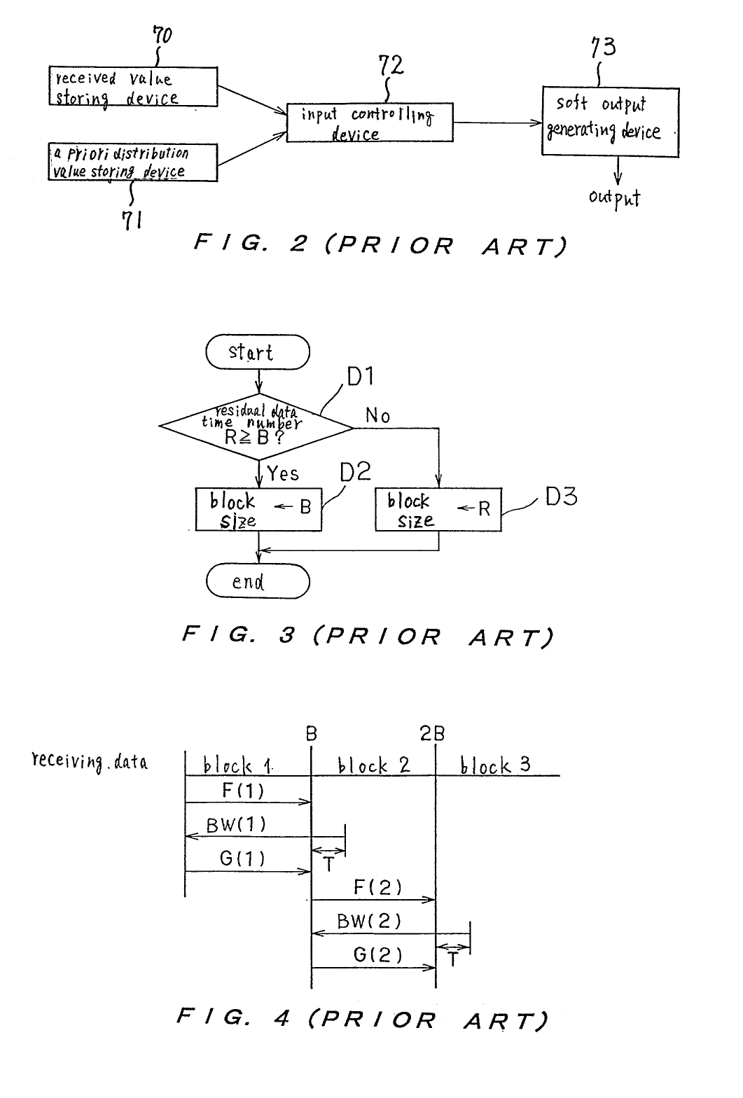

Next, the description of the operation where the error-correcting code decoding apparatus of the present embodiment is applied to the turbo decoder of FIG. 1 will be provided hereinbelow with reference to FIG. 10.

At this stage, it should be understood that the first and second decoders shown in FIG. 1 are constituted by the error-correcting code decoder shown in FIG. 5.

Further, in the description below, although an example in which two kinds of blocks are prepared will be explained, it should be noted that the operation might be similarly brought into practice when three or more kinds of blocks are employed. Furthermore, it is to be noted that the received data are stored in received value storing device 10 of the first decoder. Moreover, the processing for altering the block boundary in response to the number of repetition of the repeated decode processing is carried out by control command generating device 14 of the first decoding device.

First of all, control command generating device 14 of the first decoder sets 1 for k that is a variable for counting the number of repetition of the repeated decode processing (Step C1). Subsequently, control command generating device 14 checks to detect whether the value of k is an odd number or an even number (Step C2). When the k is detected to be an even number, control command generating device 14 commands to input controlling device 12 so that the boundaries of blocks are set as shown in (2) of FIG. 7 (Step C3), and when the k is detected to be an odd number, control command generating device 14 commands to input controlling device 12 so that the boundaries of blocks are set as shown in (1) of FIG. 7 (Step C4).

Input controlling device 12 reads the data with every block from received value storing device 10 and a priori distribution value storing device 11 according to the command of control command generating device 14, and supplies those read data to soft output generating device 13.

The above-described processes are firstly implemented by the first decoder in association with the first convolutional encoder, which is a constituent of the turbo encoder (Step C5). At this instant, the first decoder generates a soft output by every block unit designated in the step C2.

When k=1, an appropriate initial value (normally, a value which made 0 and 1 be equal probability) is set in a priori distribution value storing device 11. The extrinsic information that is the result of decoding by the first decoder is stored in an a priori distribution value storing device 11 of the second decoder. Then, while using this extrinsic information together, the decoding is carried out by the second decoder (Step C6). At this instant, the second decoder generates a soft output by every block unit designated in the step C2. The extrinsic information output from the second decoder due to the process of step C6 is stored in an a priori distribution value storing device 11 of the first decoder.

When the above-described process has been completed, control command generating device 14 of the first decoder decides as to whether or not the repeated decode processing should be continued (Step C7). This may be realized by any one of the methods, i.e., a method in which decision is made to check whether or not the number of repetition has reached a priori number, a method in which decision is made by checking an externally attached error-detecting code, and so on. When the repeated decode processing is decided to be continued, the value of k is shifted by one increment (Step C8), and returns to the step C2 to repeat the processing to the step C7.

Thus, when the sizes of the firstly processed blocks are set at different values for every block kind, depending on the number of repetition of the repeated decode processing, the setting values of the block boundaries increase to thereby increase a probability that the decoding can be achieved. Therefore, even if the margin time points T of the backward process at the block boundaries is set small, if decoding can be made in any one of the blocks, the data having no error can be decoded at a high probability without increasing the number of repetition of the repeated decode processing. Accordingly, any deterioration in the decoding performance does not occur, and the amount of calculation of the backward process can be reduced.

For example, when the turbo code in which the number of memory is three, and the coding ratio is 1/3 should be decoded under a condition that the decoding fame error ratio is 0.0001, and the size of the block B=32, there appears a difference in the coding gain of approximately 0.1 dB with T (the margin time points) =18 in the prior art method of fixing the block boundaries compared with the method of decoding the entire code trellis. Nevertheless, in the decoding method according to the present embodiment, which employs the three kinds of blocks, the same coding gain as the above can be obtained by T=12. Therefore, approximately 5% of the amount of calculation can be reduced.

While preferred embodiments of the present invention have been described using specific terms, such description is for illustrative purposes only, and it is to be understood that changes and variations may be made without departing from the spirit or scope of the following claims.

What is claimed is:

1. An error-correcting code decoding method in which received words are decoded by repetition of a predetermined decode processing, comprising the steps of:
setting a plurality of kinds of block that is a processing unit in said decode processing;
setting the size of blocks that are subjected to an initial decode processing for every said kind out of the repeated process of said decode processing at different values, respectively;
setting the size of residual blocks except for finally processed block at a predetermined reference size, respectively; and,
generating a soft output of information symbol of said received words from said received words and a priori distribution values that correspond to reliability of said information symbol of said received words by a unit of said block.

2. The error-correcting code decoding method as set forth in claim 1, wherein,
where said reference size of said block is represented by B, the number of kinds of said block is represented by n, and the number of repetition of said decode processing at the present instant is represented by k, the size of said blocks that are subjected to said initial decoding processing is made B(n+1−k)/n.

3. The error-correcting code decoding method as set forth in claim 1, wherein,
when the number of repetition of said repeated decode processing at the present instant is either one of odd and even numbers, the size of said block that is subjected to said initial decoding processing is set at a half of said predetermined reference size.

4. An error-correcting code decoding apparatus for decoding received words by repeating a predetermined decode processing comprising:
a received value storing device for storing said received words;
an a priori distribution value storing device for storing a priori distribution values corresponding to reliabilities of information symbols of said received words, respectively;
an input controlling device for reading data that are respectively necessary for decoding processing from said received value storing device and said a priori distribution value storing device;
a soft output generating device for generating soft outputs of said information symbols by a unit of said block from said received words and said a priori distribution values read by said input controlling device; and
a control command generating device for setting a plurality of kinds of block that is a processing unit in said decoding processing, for setting the size of blocks that are subjected to an initial decoding processing for every said kind out of the repeated processings of said decoding process at different values, respectively, and for setting the size of residual blocks except for finally processed block at a predetermined reference size, respectively.

5. The error-correcting code decoding apparatus as set forth in claim 4, wherein,
where said reference size of said block is represented by B, the number of kinds of said block is represented by n, and the number of repetition of said decoding processing at the present instant is represented by k, said control command generating device sets the size of said blocks that are subjected to said initial decode processing at B(n+1−k)/n.

6. The error-correcting code decoding apparatus as set forth in claim 4, wherein,
when the number of repetition of said repeated decode processing at the present instant is either one of odd and even numbers, said control command generating device set the size of said block that is subjected to said initial decode processing at a half of said predetermined reference size.
